(19) United States
(12) Patent Application Publication
(10) Pub. No.: US 2013/0239591 A1
(43) Pub. Date: Sep. 19, 2013

(54) THERMAL ELECTRIC COOLER AND METHOD

(71) Applicant: Robert R. Clarkson, Garland, TX (US)

(72) Inventor: Robert R. Clarkson, Garland, TX (US)

(73) Assignee: Raytheon Company, Waltham, MA (US)

(21) Appl. No.: 13/422,990

(22) Filed: Mar. 16, 2012

(51) Int. Cl. F25B 21/02; H01L 21/02

(52) U.S. Cl. 62/3.7; 438/54; 257/E21.002

(57) ABSTRACT

According to an embodiment of the disclosure, a thermal electric cooler is provided that includes a plurality of segments and a plurality of couplers. The segments are coupled in series to form a ladder-configuration string of P-channel chips and N-channel chips. Each segment comprises at least two substrings coupled in parallel. Each substring comprises at least one of the chips. Each of the couplers is configured to couple one of the P-channel chips to one of the N-channel chips.

### TECHNICAL FIELD

The present disclosure is directed, in general, to cooling technology and, more specifically, to a thermal electric cooler and method.

### BACKGROUND OF THE DISCLOSURE

There are many applications in which it is desirable to cool electronic or other components that generate heat or to hold the temperature of a component within a particular temperature range. Thermal electric coolers (TECs) are useful for these purposes. A conventional TEC includes an alternating string of P-channel and N-channel chips that use the Peltier effect to move heat from one surface to another when current is passed through the chips. In general, as a solid-state device, a TEC is a more reliable alternative to working-fluid systems. However, TECs have been difficult to make very highly reliable because when a single chip in the TEC fails, the entire TEC becomes inoperable.

In order to overcome this disadvantage, attempts have been made to improve the reliability of a TEC. For example, TECs have been designed with completely redundant subsystems. That is, a TEC may have a certain number of chips for cooling and the same number of chips to be used as a backup in case the first set of chips fails. However, using this arrangement, the backup set of chips becomes a parasitic load for the first set of chips. Thus, to overcome this load, additional chips are needed. As a result, the TEC may need significantly more than twice the number of chips of a standard TEC.

For another example, multiple TECs may be implemented with a mechanical actuator. When a first TEC fails, the mechanical actuator may be used to physically move the first TEC away from the component that is to be cooled and to physically move a second, functioning TEC into contact with the component. However, this solution introduces physical moving parts that are subject to failure.

As yet another example, a piston/cylinder thermal disconnect has been implemented for use with a TEC. For this type of system, a TEC cools a sleeve with a large coefficient of thermal expansion. The cooled sleeve shrinks around a piston, making contact with the piston. If the TEC fails, the sleeve heats up, expands, and thus releases from the piston. However, this solution also introduces complexity and additional mechanical parts that are subject to failure.

### SUMMARY OF THE DISCLOSURE

This disclosure provides an improved thermal electric cooler and method.

In one embodiment, a thermal electric cooler is provided that includes a plurality of segments and a plurality of couplers. The segments are coupled in series to form a ladder-configuration string of P-channel chips and N-channel chips. Each segment comprises at least two substrings coupled in parallel. Each substring comprises at least one of the chips. Each of the couplers is configured to couple one of the P-channel chips to one of the N-channel chips.

In another embodiment, a thermal electric cooler is provided that includes a top substrate, a bottom substrate, a plurality of P-channel chips and N-channel chips, and a plurality of couplers. The P-channel chips and the N-channel chips are coupled between the top substrate and the bottom substrate in rows and columns. Each of the columns comprises an alternating pattern of the P-channel chips and the N-channel chips. Each of the rows comprises an alternating pattern of pairs of the P-channel chips and pairs of the N-channel chips. Each of the couplers is configured to couple one of the P-channel chips to one of the N-channel chips.

In yet another embodiment, a method is provided that includes coupling at least two substrings in parallel to form each of a plurality of segments. The segments are coupled in series to form a ladder-configuration string of P-channel chips and N-channel chips for a thermal electric cooler. Each substring comprises at least one of the chips.

Other technical features may be readily apparent to one skilled in the art from the following figures, descriptions, and claims.

### BRIEF DESCRIPTION OF THE DRAWINGS

For a more complete understanding of the present disclosure, reference is now made to the following description taken in conjunction with the accompanying drawings, in which:

FIG. 1 illustrates a system for providing thermal electric cooling in accordance with the present disclosure;

FIG. 2 illustrates the thermal electric cooler of FIG. 1 in accordance with the present disclosure;

FIGS. 3A-C illustrate the implementation of a ladder-configuration string of chips for the thermal electric cooler of FIG. 2 in accordance with alternate embodiments of the present disclosure;

FIG. 4 illustrates a schematic diagram of the thermal electric cooler of FIG. 2 implementing the ladder-configuration string of FIG. 3C in accordance with the present disclosure;

FIGS. 5A-B illustrate a physical layout of the thermal electric cooler of FIG. 4 in accordance with the present disclosure; and

FIG. 6 is a flowchart illustrating a method for providing thermal electric cooling using the thermal electric cooler of FIG. 2 in accordance with the present disclosure.

### DETAILED DESCRIPTION

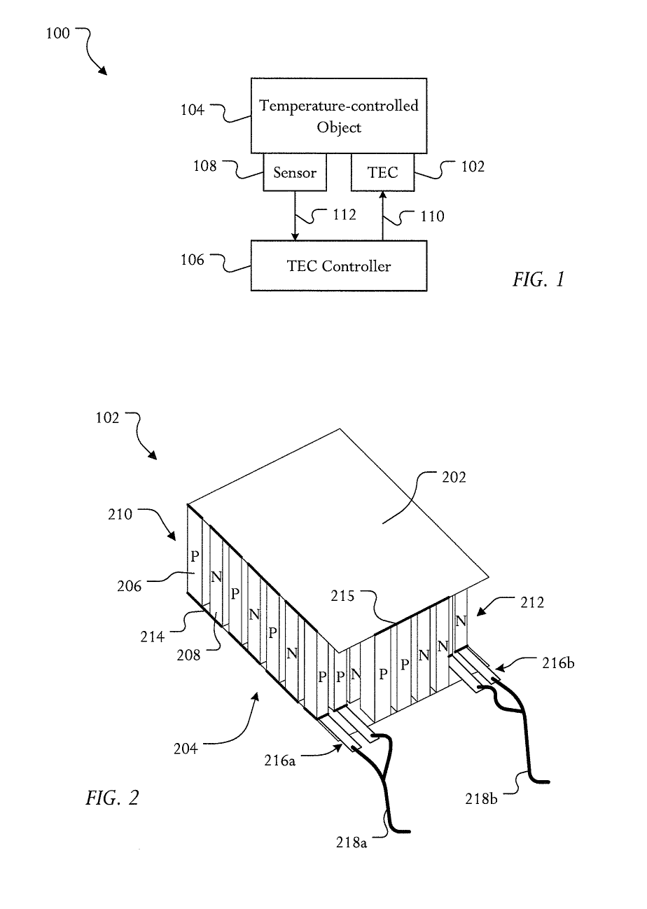

FIGS. 1 through 6, discussed below, and the various embodiments used to describe the principles of the present disclosure in this patent document are by way of illustration only and should not be construed in any way to limit the scope of the disclosure. Those skilled in the art will understand that the principles of the present disclosure may be implemented using any number of techniques, whether currently known or not. Additionally, the drawings are not necessarily drawn to scale.

FIG. 1 illustrates a system 100 for providing thermal electric cooling in accordance with the present disclosure. The embodiment of the system 100 shown in FIG. 1 is for illustration only. Other embodiments of the system 100 could be used without departing from the scope of this disclosure.

The system 100 comprises a thermal electric cooler (TEC) 102, a temperature-controlled object 104, a TEC controller 106 and a temperature sensor 108. As described in more detail below, the TEC 102 comprises a plurality of alternating P-channel and N-channel chips in a ladder-configuration string. The TEC 102 is configured to cool and/or heat the temperature-controlled object 104. For example, the TEC 102 may be placed in physical contact with the temperature-controlled object 104. Based on a control signal 110 from the TEC controller 106, the TEC 102 may provide cooling on a first side of the TEC 102 and generate heat on an opposite, second side of the TEC 102. The control signal 110 may comprise a controlled DC drive current. A heat sink (not shown in FIG. 1) may be coupled to the second side of the TEC 102 to provide release for the generated heat.

The TEC controller 106 is configured to generate the control signal 110 based on a temperature signal 112 received from the temperature sensor 108. The temperature sensor 108 is configured to sense a temperature of the temperature-controlled object 104. For example, the temperature sensor 108 may be placed in physical contact with the temperature-controlled object 104 relatively close to the TEC 102 or in any suitable location.

Thus, based on the temperature of the temperature-controlled object 104 as sensed by the temperature sensor 108 and provided to the TEC controller 106 via the temperature signal 112, the TEC controller 106 may be configured to generate the control signal 110 for the TEC 102, resulting in the TEC 102 providing cooling and/or heating such that the temperature of the temperature-controlled object 104 is moved into and/or maintained within a desired temperature range.

FIG. 2 illustrates the TEC 102 in accordance with the present disclosure. The embodiment of the TEC 102 shown in FIG. 2 is for illustration only. Other embodiments of the TEC 102 could be used without departing from the scope of this disclosure.

The TEC 102 comprises a top substrate 202, a bottom substrate 204, a plurality of P-channel chips 206, and a plurality of N-channel chips 208. The top substrate 202 and the bottom substrate 204 may each comprise a ceramic or other suitable material that is a relatively good heat conductor and a relatively good electrical insulator. The P-channel chips 206 may each comprise a p-type semiconductor and the N-channel chips 208 may each comprise an n-type semiconductor. The P-channel chips 206 and N-channel chips 208 are arranged alternately in columns 210 of the TEC 102 and in alternating pairs in rows 212 of the TEC 102.

The TEC 102 also comprises a plurality of couplers 214, a plurality of shorting bars 215 and a plurality of connectors 216. In the columns 210, each chip 206 and 208 is electrically coupled to a previous chip and a next chip with a coupler 214. The chips 206 and 208 at the ends of the columns 210 may also be coupled to a chip 206 or 208 in an adjacent column 210 with a coupler 214. Thus, an electrical signal may travel up through a P-channel chip 206, across a coupler 214, down an N-channel chip 208, across another coupler 214, and so on. Alternatively, an electrical signal may travel down through a P-channel chip 206, across a coupler 214, up an N-channel chip 208, across another coupler 214, and so on. Depending on the direction of the electrical signal, the TEC 102 may extract heat using either the top substrate 202 or the bottom substrate 204 and generate heat through the other substrate 202 or 204.

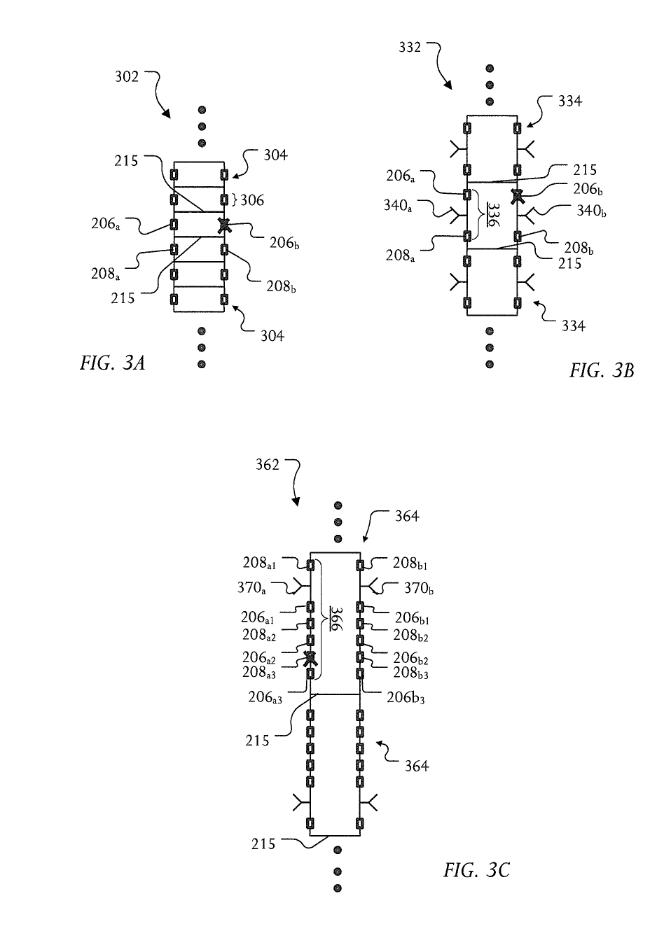

As described in more detail below in connection with FIGS. 3-5, in the rows 212, the shorting bars 215 electrically couple two pairs of chips 206 and 208 to each other. Thus, each shorting bar 215 couples a pair of P-channel chips 206 and a pair of N-channel chips 208 together. In this way, the shorting bars 215 couple segments of the chips 206 and 208 to each other, which based on the configuration of the TEC 102 allows most or all of the functioning chips 206 and 208 to continue functioning when one or more chips 206 or 208 fail.

A first pair of connectors 216a couples a first drive wire 218a to a pair of P-channel chips 206, and a second pair of connectors 216b couples a second drive wire 218b to a pair of N-channel chips 208. It will be understood that two separate wires providing a same signal may replace the first drive wire 218a and two separate wires providing another same signal may replace the second drive wire 218b. For this embodiment, a single connector 216a and a single connector 216b may be replace the pairs of connectors 216a and 216b, with the single connector 216a electrically coupled to the two P-channel chips 206 and the single connector 216b electrically coupled to the two N-channel chips 208.

The TEC controller 106 of FIG. 1 (not shown in FIG. 2) is configured to provide the control signal 110 to the TEC 102 through the drive wires 218a-b. Based on the polarity of the signal provided over the first drive wire 218a to the first connectors 216a as compared to the signal provided over the second drive wire 218b to the second connectors 216b, the TEC controller 106 is configured to control the direction of the electrical signal through the TEC 102, thereby controlling whether the TEC 102 provides cooling through the top substrate 202 or the bottom substrate 204. For example, for the illustrated configuration, when a negative signal is applied through the first drive wire 218a and a positive signal is provided through the second drive wire 218b, the top substrate 202 may provide cooling.

As described in more detail below, instead of being arranged in a serial string, the chips 206 and 208 are arranged in a ladder-configuration string that provides a plurality of parallel-coupled partner substrings. As a result, when a single chip 206 or 208 fails, the TEC 102 continues to function and provide cooling and/or heating. Furthermore, the TEC 102 is able to continue functioning with multiple chip failures as long as none of the chips 206 and 208 that has failed is in a partner substring of a substring that includes another failed chip 206 or 208. By choosing a number of chips 206 and 208 to include in each substring, the probability of failure can be varied. Thus, when fewer chips 206 and 208 are included in each substring, the probability of failure for the TEC 102 decreases, and when more chips 206 and 208 are included in each substring, the probability of failure for the TEC 102 increases.

Although FIG. 2 illustrates one example of a TEC 102, various changes may be made to FIG. 2. For example, the makeup and arrangement of the TEC 102 are for illustration only. Components could be added, omitted, combined, subdivided, or placed in any other suitable configuration according to particular needs. For example, although FIG. 2 shows only a single-stage TEC 102, the same principles described above may be used to implement a multi-stage thermal electric cooler.

FIGS. 3A-C illustrate the implementation of a ladder-configuration string of chips 206 and 208 for the TEC 102 in accordance with alternate embodiments of the present disclosure.

FIG. 3A illustrates part of a ladder-configuration string 302 that includes a plurality of segments 304 of parallel-coupled substrings 306. For this embodiment, each substring 306 comprises a single P-channel chip 206 or a single N-channel chip 208. As shown in FIG. 3A, shorting bars 215 couple the substrings 306 of each segment 304 together at both ends. The shorting bar 215 also couples each segment 304 to a subsequent segment 304.

Each segment 304 comprises either a first substring 306 including a P-channel chip 206 and a second partner substring 306 including another P-channel chip 206 or a first substring 306 including an N-channel chip 208 and a second partner substring 306 including another N-channel chip 208. For this embodiment, if a chip 206 or 208 fails, such as the P-channel chip 206_{b} in FIG. 3A, the current that would have passed through the failed chip 206_{b} instead passes through the partner substring 306, which is the P-channel chip 206ₐ. In this situation, the current passing through the functioning chip 206ₐ is twice as much as the current passing through the remaining chips 206 and 208 in the other segments 304. This may result in the functioning chip 206ₐ cooling (or heating) less efficiently when the current is originally at or near a level corresponding to 100% efficiency. However, this does not increase the probability of failure for that chip 206ₐ. In addition, the chips 206 and 208 in the other segments 304 are not affected by the failure of chip 206_{b} and continue to function as before. If the original current level is much lower, such as a level corresponding to 50% of the current required to function at maximum efficiency, for example, the chip 206ₐ will function at 100% efficiency after the failure of the chip 206_{b}.

Therefore, using the ladder-configuration string 302, the TEC 102 continues to operate and provide cooling (or heating) until chips in both partner substrings 306 of the same segment 304 fail. Thus, for the illustrated example, the TEC 102 would continue to function until the chip 206ₐ failed, or until chips 208a and 208b both fail, or chips in both partner substrings 306 of a different segment 304 fail.

FIG. 3B illustrates part of a ladder-configuration string 332 that includes a plurality of segments 334 of parallel-coupled substrings 336. For this embodiment, each substring 336 comprises a P-channel chip 206 and an N-channel chip 208. As shown in FIG. 3B, shorting bars 215 couple the partner substrings 336 of each segment 334 together at both ends. The shorting bar 215 also couples each segment 334 to a subsequent segment 334.

For this embodiment, if a chip 206 or 208 fails, such as the P-channel chip 206_{b} in FIG. 3B, the current that would have passed through the substring 336 that includes the failed chip 206_{b} instead passes through the partner substring 336, which includes the P-channel chip 206ₐ and the N-channel chip 208ₐ. In this situation, the current passing through the functioning chips 206 and 208 of the partner substring 336 is twice as much as the current passing through the chips 206 and 208 in the other segments 334. This may result in the chips 206ₐ and 208ₐ in the partner substring 336 cooling (or heating) less efficiently when the current is originally at or near a level corresponding to 100% efficiency. However, this does not increase the probability of failure for those chips 206ₐ and 208ₐ. In addition, the chips 206 and 208 in the other segments 334 are not affected by the failure of chip 206_{b} and continue to function as before. If the original current level is much lower, such as a level corresponding to 50% of the current required to function at maximum efficiency, for example, the chips 206ₐ and 208ₐ will function at 100% efficiency after the failure of the chip 206_{b}.

Therefore, using the ladder-configuration string 332, the TEC 102 continues to operate and provide cooling (or heating) until chips in both partner substrings 336 of the same segment fail. Thus, for the illustrated example, the TEE 102 would continue to function until one of the chips 206ₐ or 208ₐ failed or until chips 206 or 208 in both partner substrings 336 of a different segment 334 fail.

The embodiment of FIG. 3B also includes test points 340. A test point 340 may be provided within each substring 336. Using the test points 340, a determination can be made as to whether any of the chips 206 and 208 in the substring 336 has failed. For example, for the illustrated embodiment, a voltage level may be measured at the test point 340ₐ and a voltage level may be measured at the test point 340_{b}. If the voltage levels at the test points 340ₐ and 340_{b} in partner substrings 336 of the same segment 334 are the same, it can be assumed that all of the chips 206 and 208 in the segment 334 are functioning. However, if the voltage levels at the test points 340ₐ and 340_{b} are different from each other, at least one of the chips 206 and 208 in the segment 334 has failed. Thus, for the example of FIG. 3B, based on a comparison to the voltage level measured at the test point 340ₐ, the voltage level measured at the test point 340_{b} will indicate a failure of one of the chips 206_{b} and 208_{b}.

FIG. 3C illustrates part of a ladder-configuration string 362 that includes a plurality of segments 364 of parallel-coupled substrings 366. For this embodiment, each substring 366 comprises three P-channel chips 206 and three N-channel chips 208. As shown in FIG. 3C, shorting bars 215 couple the partner substrings 366 of each segment 364 together at both ends. The shorting bar 215 also couples each segment 364 to a subsequent segment 364.

For this embodiment, if a chip 206 or 208 fails, such as the N-channel chip 208ₐ₃ in FIG. 3C, the current that would have passed through the substring 366 that includes the failed chip 208ₐ₃ instead passes through the partner substring 366, which includes the P-channel chips 206_{b1}, 206_{b2}, and 206_{b3} and the N-channel chips 208_{b1}, 208_{b2}, and 208_{b3}. In this situation, the current passing through the functioning chips 206_{b1-3} and 208_{b1-3} of the partner substring 366 is twice as much as the current passing through the chips 206 and 208 in the other segments 364. This may result in the chips 206_{b1-3} and 208_{b1-3} in the partner substring 366 cooling (or heating) less efficiently when the current is originally at or near a level corresponding to 100% efficiency. However, this does not increase the probability of failure for those chips 206_{b1-3} and 208_{b1-3}. In addition, the chips 206 and 208 in the other segments 364 are not affected by the failure of chip 208ₐ₃ and continue to function as before. If the original current level is much lower, such as a level corresponding to 50% of the current required to function at maximum efficiency, for example, the chips 206_{b1-3} and 208_{b1-3} will function at 100% efficiency after the failure of the chip 208ₐ₃.

Therefore, using the ladder-configuration string 362, the TEC 102 continues to operate and provide cooling (or heating) until chips in both partner substrings 366 of the same segment 364 fail. Thus, for the illustrated example, the TEC 102 would continue to function until one of the chips 206_{b1-3} or 208_{b1-3} failed or until chips 206 or 208 in both partner substrings 366 of a different segment 364 fail.

The embodiment of FIG. 3C also includes test points 370. A test point 370 may be provided within each substring 366. Using the test points 370, a determination can be made as to whether any of the chips 206 and 208 in the substring 366 has failed. For example, for the illustrated embodiment, a voltage level may be measured at the test point 370ₐ and a voltage level may be measured at the test point 370_{b}. If the voltage levels at the test points 370, and 370_{b} in partner substrings 366 of the same segment 364 are the same, it can be assumed that all of the chips 206 and 208 in the segment 364 are functioning. However, if the voltage levels at the test points 370ₐ and 370_{b} are different from each other, at least one of the chips 206 and 208 in the segment 364 has failed. Thus, for the example of FIG. 3C, based on a comparison to the voltage level measured at the test point 370_{b}, the voltage level measured at the test point 370ₐ will indicate a failure of one of the chips 206ₐ₁₋₃ and 208ₐ₁₋₃.

Although FIGS. 3A-C illustrate three examples of ladder-configuration strings 302, 332 and 362 for a TEC 102, various changes may be made to these examples. For example, the makeup and arrangement of the strings 302, 332 and 362 are for illustration only. Components could be added, omitted, combined, subdivided, or placed in any other suitable configuration according to particular needs. For example, although FIG. 3A shows only six segments 304, FIG. 3B shows only three segments 334, and FIG. 3C shows only two segments 364, any of these ladder-configuration strings 302, 332 and/or 362 may comprise any suitable number of segments 304, 334 and 364, as indicated by the sequence of three dots on either side of the illustrated strings 302, 332 and 362. Also, although the illustrated embodiments include two partner substrings 306, 336 and 366 in each segment 304, 334 and 364, the segments 304, 334 and 364 could be implemented with any suitable number of partner substrings 306, 336 and 366. Finally, although the illustrated embodiments include one chip 206 or 208, two chips 206 and 208, and six chips 206 and 208 in each substring 306, 336 and 366, respectively, each substring 306, 336 and 366 may comprise any suitable number of chips 206 and 208.

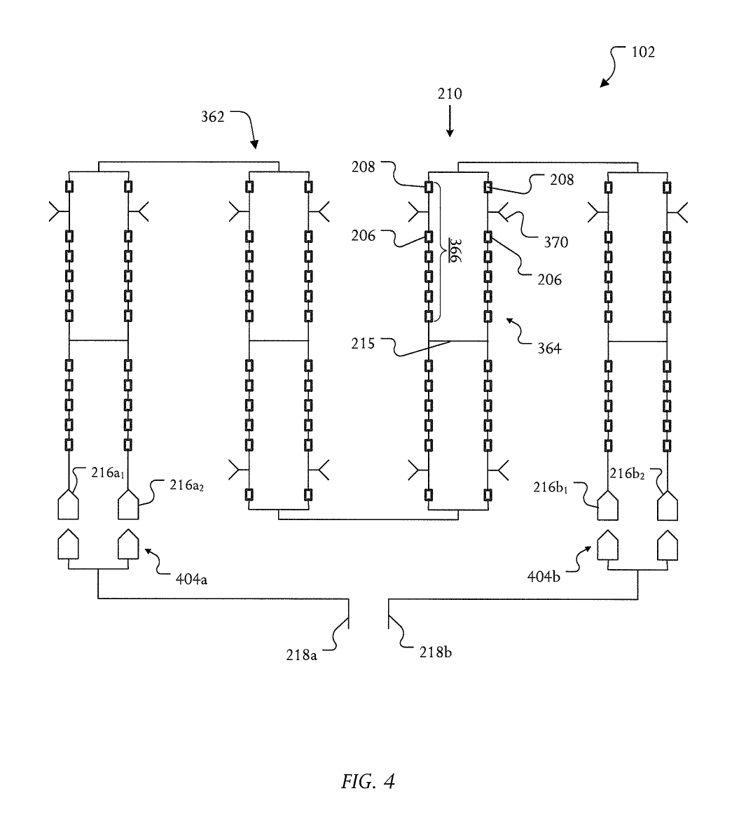

FIG. 4 illustrates a schematic diagram of the TEC 102 implementing the ladder-configuration string 362 of FIG. 3C in accordance with the present disclosure. For this example, the TEC 102 comprises a ladder-configuration string 362 including eight segments 364, with each segment 364 including two partner substrings 366. A first and last segment 364 in the string 362 includes five chips 206 and 208, while the remaining substrings 366 each comprise six chips 206 and 208 (three P-channel chips 206 and three N-channel chips 208). Also, each substring 366 other than the substrings 366 in the first and last segments 364 includes a test point 370.

For the illustrated embodiment, the first drive wire 218a is coupled to the first pair of connectors 216a of the TEC 102 as indicated by a first pair of controller connectors 404a of the TEC controller 106 (not shown in FIG. 4), and the second drive wire 218b is coupled to the second pair of connectors 216b of the TEC 102 as indicated by a second pair of controller connectors 404b of the TEC controller 106. As shown in FIG. 4, the ladder-configuration string 362 may form a serpentine string of segments 364 in order to provide a roughly square-shaped TEC 102 or any other desired shape. For this embodiment, the shorting bars 215 are provided half-way across each column 210 of segments 364, i.e., each column 210 includes two segments 364.

Although FIG. 4 illustrates one example of a TEC 102, various changes may be made to FIG. 4. For example, the makeup and arrangement of the TEC 102 are for illustration only. Components could be added, omitted, combined, subdivided, or placed in any other suitable configuration according to particular needs. For example, although FIG. 4 shows only eight segments 364, the TEC 102 may comprise any suitable number of segments 364. Also, although the illustrated embodiments include two partner substrings 366 in each segment 364, the TEC 102 could be implemented with any suitable number of partner substrings 366 in each segment 364. In addition, although the illustrated embodiment includes five chips 206 and 208 in the substrings 366 of the first and last segments 364 of the string 362 and includes six chips 206 and 208 in each of the other substrings 366, any suitable number of chips 206 and 208 may be included in each of the substrings 366. Finally, although the illustrated embodiment includes two segments 364 in each column 210 of the TEC 102, each column 210 may include any suitable number of segments 364.

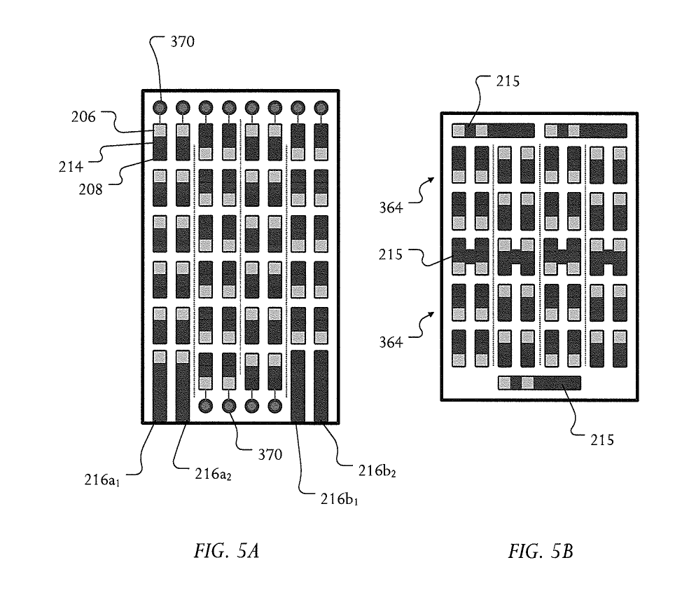

FIGS. 5A-B illustrate a physical layout of the TEC 102 of FIG. 4 in accordance with the present disclosure. FIG. 5A corresponds to a top view of the bottom substrate 204, while FIG. 5B corresponds to a view through the top of the top substrate 202. Thus, as described above in connection with FIGS. 2-4, the TEC 102 comprises P-channel chips 206, N-channel chips 208, couplers 214 and connectors 216a and 216b. The TEC 102 also comprises segments 364 coupled together by shorting bars 215 and test points 370. For this embodiment, the electrical connections to the TEC 102 for the TEC controller 106, i.e., the connectors 216a₁₋₂ and 216b₁₋₂, as well as the electrical connections to the TEC 102 for the test points 370, are provided at the periphery of the bottom substrate 204. Thus, this arrangement does not require any connections to the top substrate 202, which could impact the cooling efficiency of the TEC 102, and does not require additional routing for the test points 370 because the connections are provided at the periphery of the substrate 202.

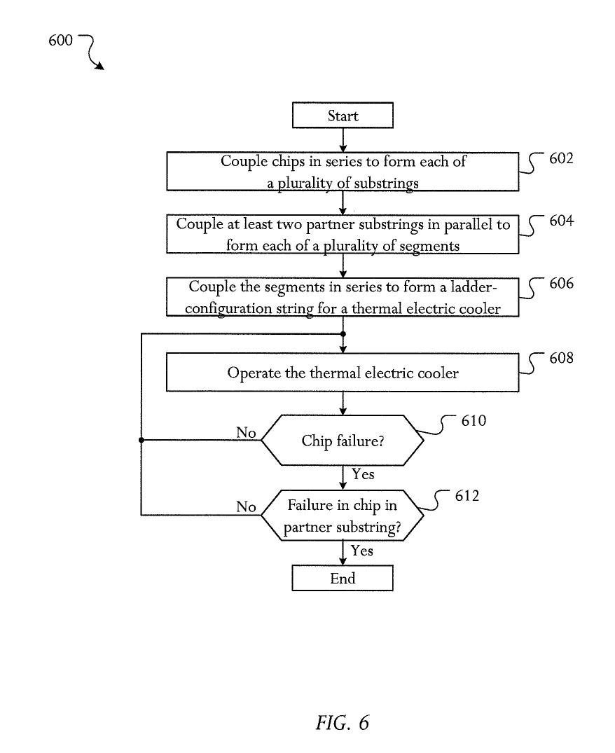

FIG. 6 is a flowchart illustrating a method 600 for providing thermal electric cooling using the TEC 102 in accordance with the present disclosure. The method 600 shown in FIG. 6 is for illustration only. Thermal electric cooling may be provided using the thermal electric cooler 102 in any other suitable manner without departing from the scope of this disclosure.

A plurality of chips 206 and 208 are coupled in series to form each of a plurality of substrings 336 or 366 (step 602). It will be understood that this step may be omitted for substrings 306 that include a single chip 206 or 208. At least two partner substrings 306, 336 or 366 are coupled in parallel with each other to form each of a plurality of segments 304, 334 or 364 (step 604). The segments 304, 334 or 364 are coupled in series to form a ladder-configuration string 302, 332 or 362 for the TEC 102 (step 606).

The TEC 102 is operated to provide cooling and/or heating of a temperature-controlled object 104 (step 608). For example, a temperature sensor 108 may provide a temperature signal 112 to a TEC controller 106 indicating a current temperature of the temperature-controlled object 104. Based on the temperature, the TEC controller 106 generates a control signal 110 and provides the control signal 110 to the TEC 102. For a particular example, the control signal 110 may be provided to the TEC 102 through drive wires 218a and 218b. Based on the control signal 110, the TEC 102 cools and/or heats the temperature-controlled object 104 via the substrate 202 or 204 that is coupled to the temperature-controlled object 104.

When no chip has failed (step 610), the TEC 102 continues to operate (step 608). When a chip 206 or 208 does fail (step 610), if there has been no failure in a chip 206 or 208 in a partner substring 306, 336 or 366 of the chip 206 or 208 that has just failed (step 612), the TEC 102 continues to operate (step 608). However, when a chip 206 or 208 fails (step 610) and there has been a failure in a chip 206 or 208 in a partner substring 306, 336 or 366 of the chip 206 or 208 that has just failed (step 612), the TEC 102 no longer operates and the method comes to an end.

In this way, the TEC 102 may continue to function effectively even after multiple chip failures, as long as the chips 206 and 208 that have failed are not in substrings 306, 336 or 366 whose partner substring 306, 336 or 366 includes a failed chip 206 or 208. Also, because the TEC 102 includes no backup chips 206 and 208, the high parasitic thermal losses associated with stand-by methods is eliminated and a large number of extra chips 206 and 208 is not required for a backup system.

In addition, by implementing test points 340 or 370, verification may be provided that the TEC 102 has not already absorbed a failure before deployment. Furthermore, external switching, active fail-over circuitry or control, moving mechanical components, thermal connection and disconnection, and electrical switching may all be eliminated. The TEC 102 also improves size, weight, and power requirements as compared to conventional TECs. Finally, when a failure of a chip 206 or 208 does occur, only a small percentage of the TEC 102 becomes a parasitic load. This percentage may be modified based on the number of chips 206 and 208 included in each segment 304, 334 and 364 and may be as small as 1% or less.

Although FIG. 6 illustrates one example of a method 600 for providing thermal electric cooling using the thermal electric cooler 102, various changes may be made to FIG. 6. For example, while shown as a series of steps, various steps in FIG. 6 could overlap, occur in parallel, occur in a different order, or occur multiple times. Also, it will be understood that no component is actually making determinations in the decision steps 610 and 612, but that these steps simply illustrate the operation of the TEC 102.

Modifications, additions, or omissions may be made to the systems, apparatuses, and methods described herein without departing from the scope of the disclosure. For example, the components of the systems and apparatuses may be integrated or separated. Moreover, the operations of the systems and apparatuses may be performed by more, fewer, or other components. The methods may include more, fewer, or other steps. Additionally, as described above, steps may be performed in any suitable order.

It may be advantageous to set forth definitions of certain words and phrases used throughout this patent document. The term “couple” and its derivatives refer to any direct or indirect communication between two or more elements, whether or not those elements are in physical contact with one another. The terms “include” and “comprise,” as well as derivatives thereof, mean inclusion without limitation. The term “or” is inclusive, meaning and/or. The term “each” refers to each member of a set or each member of a subset of a set. Terms such as “over” and “under” may refer to relative positions in the figures and do not denote required orientations during manufacturing or use. Terms such as “higher” and “lower” denote relative values and are not meant to imply specific values or ranges of values. The phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like.

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A thermal electric cooler, comprising:
a plurality of segments coupled in series to form a ladder-configuration string of P-channel chips and N-channel chips, wherein each segment comprises at least two substrings coupled in parallel, and wherein each substring comprises at least one of the chips; and
a plurality of couplers, wherein each of the couplers is configured to couple one of the P-channel chips to one of the N-channel chips.

2. The thermal electric cooler of claim 1, further comprising a top substrate and a bottom substrate, wherein the segments are coupled between the top substrate and the bottom substrate.

3. The thermal electric cooler of claim 1, further comprising:
a first pair of connectors configured to couple a first drive wire to a first one of the segments in the ladder-configuration string; and
a second pair of connectors configured to couple a second drive wire to a last one of the segments in the ladder-configuration string.

4. The thermal electric cooler of claim 3, wherein the first drive wire is configured to provide a first signal from a thermal electric cooler controller to the first segment and the second drive wire is configured to provide a second signal from the thermal electric cooler controller to the last segment.

5. The thermal electric cooler of claim 1, further comprising a plurality of shorting bars, wherein each of the shorting bars is configured to couple two of the P-channel chips and two of the N-channel chips to each other.

6. The thermal electric cooler of claim 1, further comprising a plurality of test points, wherein each of the sub strings comprises one of the test points.

7. The thermal electric cooler of claim 6, further comprising a top substrate and a bottom substrate having a periphery, wherein the segments are coupled between the top substrate and the bottom substrate, and wherein the test points are located at the periphery of the bottom substrate.

8. The thermal electric cooler of claim 1, wherein each of the P-channel chips comprises a p-type semiconductor and each of the N-channel chips comprises an n-type semiconductor.

9. A thermal electric cooler, comprising:
a top substrate;
a bottom substrate;
a plurality of P-channel chips and a plurality of N-channel chips coupled between the top substrate and the bottom substrate in rows and columns, wherein each of the columns comprises an alternating pattern of the P-channel chips and the N-channel chips and each of the rows comprises an alternating pattern of pairs of the P-channel chips and pairs of the N-channel chips; and
a plurality of couplers, wherein each of the couplers is configured to couple one of the P-channel chips to one of the N-channel chips.

10. The thermal electric cooler of claim 9, further comprising a plurality of segments coupled in series to form a ladder-configuration string of the P-channel chips and the N-channel chips, wherein each segment comprises at least two substrings coupled in parallel, and wherein each substring comprises at least one of the chips.

11. The thermal electric cooler of claim 10, further comprising:
a first pair of connectors configured to couple a first drive wire to a first one of the segments in the ladder-configuration string; and
a second pair of connectors configured to couple a second drive wire to a last one of the segments in the ladder-configuration string.

12. The thermal electric cooler of claim 11, wherein the first drive wire is configured to provide a first signal from a thermal electric cooler controller to the first segment and the second drive wire is configured to provide a second signal from the thermal electric cooler controller to the last segment.

13. The thermal electric cooler of claim 12, wherein the first signal and the second signal cause one of the top substrate and the bottom substrate to provide cooling.

14. The thermal electric cooler of claim 10, further comprising a plurality of test points, wherein each of the substrings comprises one of the test points.

15. The thermal electric cooler of claim 14, wherein the bottom substrate has a periphery, and wherein the test points are located at the periphery of the bottom substrate.

16. The thermal electric cooler of claim 9, further comprising a plurality of shorting bars, wherein each of the shorting bars is configured to couple two of the P-channel chips and two of the N-channel chips to each other.

17. The thermal electric cooler of claim 9, wherein each of the P-channel chips comprises a p-type semiconductor and each of the N-channel chips comprises an n-type semiconductor.

18. A method comprising:
coupling at least two substrings in parallel to form each of a plurality of segments; and
coupling the segments in series to form a ladder-configuration string of P-channel chips and N-channel chips for a thermal electric cooler, wherein each substring comprises at least one of the chips.

19. The method of claim 18, further comprising coupling a plurality of the chips in series to form each of the substrings.

20. The method of claim 18, wherein each of the substrings comprises a single chip, and wherein each segment comprises one of: two P-channel chips and two N-channel chips.
